(19) United States
(12) Patent Application Publication
(10) Pub. No.: US 2012/0299132 A1
(43) Pub. Date: Nov. 29, 2012

(54) TUNNELING MAGNETORESISTANCE (TMR) READ SENSOR WITH LOW-CONTACT-RESISTANCE INTERFACES

(75) Inventor: Tsann Lin, Saratoga, CA (US)

(73) Assignee: Hitachi Global Storage Technologies Netherlands B.V., Amsterdam, NL (unknown)

(21) Appl. No.: 13/117,922

(22) Filed: May 27, 2011

(51) Int. Cl. H01L 29/82; H01L 21/02

(52) U.S. Cl. 257/421; 438/3; 257/E29.323; 257/E21.002

(57) ABSTRACT

The invention provides a TMR read sensor with low-contact-resistance metal/metal, metal/oxide and oxide/metal interfaces. The low-contact-resistance metal/metal interfaces in a reference or sense layer structure are in-situ formed in a high-vacuum deposition module of a sputtering system, without exposures to low vacuum in a transfer module and damages caused by a plasma treatment conducted in an etching module. The low-contact-resistance metal/oxide interface is formed by utilizing a thin Co—Fe—B reference layer and a thick Co—Fe reference layer to reduce boron diffusion and segregation caused by annealing. The low-contact-resistance oxide/metal interface is formed by replacing a Co—Fe—B sense layer with a Co-rich Co—Fe sense layer to eliminate boron diffusion and segregation caused by annealing. With the low-contact-resistance metal/metal, metal/oxide and oxide/metal interfaces, the TMR read sensor exhibits a junction resistance-area product of below 0.6 Ω-μm², while maintaining a low ferromagnetic coupling field and a high TMR coefficient.

### FIELD OF THE INVENTION

The invention relates to non-volatile magnetic storage devices and more particularly to a magnetic disk drive including a tunneling magnetoresistance (TMR) read sensor with low-contact-resistance interfaces.

### BACKGROUND OF THE INVENTION

One of many extensively used non-volatile magnetic storage devices is a magnetic disk drive that includes a rotatable magnetic disk and an assembly of write and read heads. The assembly of write and read heads is supported by a slider that is mounted on a suspension arm. The suspension arm is supported by an actuator that can swing the suspension arm to place the slider with its air bearing surface (ABS) over the surface of the magnetic disk.

When the magnetic disk rotates, an air flow generated by the rotation of the magnetic disk causes the slider to fly on a cushion of air at a very low elevation (fly height) over the magnetic disk. When the slider rides on the air, the actuator moves the suspension arm to position the assembly of write and read heads over selected data tracks on the magnetic disk. The write and read heads write and read data in the selected data tracks, respectively. Processing circuitry connected to the write and read heads then operates according to a computer program to implement writing and reading functions, respectively.

The write head includes a magnetic write pole and a magnetic return pole that are magnetically connected with each other at a region away from the ABS, and an electrically conductive write coil surrounding the write head. In a writing process, the electrically conductive write coil induces magnetic fluxes in the write head. The magnetic fluxes form a magnetic write field emitting from the magnetic write pole to the magnetic disk in a direction perpendicular to the surface of the magnetic disk. The magnetic write field writes data in the selected data tracks, and then returns to the magnetic return pole so that it will not erase previously written data in adjacent data tracks.

The read head includes a read sensor that is electrically connected with lower and upper ferromagnetic shields, but is electrically separated by insulation layers from longitudinal bias layers in two side regions. In a reading process, the read head passes over data in a selected data track, and magnetic fields emitting from the data modulate the resistance of the read sensor. A change in the resistance of the read sensor is detected by a sense current passing through the read sensor, and is then converted into a voltage change that generates a read signal. The resulting read signal is used to decode data in the selected data track.

A tunneling magnetoresistance (TMR) read sensor is typically used in the read head. The TMR read sensor includes a nonmagnetic insulating barrier layer sandwiched between a ferromagnetic reference layer and a ferromagnetic sense layer. The thickness of the barrier layer is chosen to be less than the mean free path of conduction electrons passing through the TMR read sensor. The magnetization of the reference layer is pinned in a direction perpendicular to the ABS, while the magnetization of the sense layer is oriented in a direction parallel to the ABS. When passing the sense current through the TMR read sensor, the conduction electrons are scattered at lower and upper interfaces of the barrier layer. When receiving a magnetic field emitting from data in the selected data track, the magnetization of the reference layer remains pinned while that of the sense layer rotates. Scattering decreases as the magnetization of the sense layer rotates towards that of the reference layer, but increases as the magnetization of the sense layer rotates away from that of the reference layer. This scattering variation induces a tunneling effect characterized by a change in the resistance of the TMR read sensor in proportion to the magnitude of the magnetic field and cos θ, where θ is an angle between the magnetizations of the reference and sense layers. The change in the resistance of the TMR read sensor is then detected by the sense current and converted into a voltage change that is processed as a read signal.

The TMR read sensor has been progressively miniaturized for magnetic recording at higher linear and track densities. Its thickness, which defines a read gap, is reduced by utilizing thinner reference, barrier, sense or other layers, in order to increase linear densities. Its width, which defines a track width, is reduced by patterning with an advanced photolithographic tool, in order to increase track densities. In this miniaturization progress of the TMR read sensor, its resistance will progressively increase so that electronic noises may becomes significant and electrostatic discharges may occur. It is thus crucial to control the resistance to below a safety margin to ensure the feasibility of the TMR read sensor miniaturized for performing magnetic recording at higher linear and track densities.

### SUMMARY OF THE INVENTION

The invention provides a TMR read sensor with low-contact-resistance metal/metal, metal/oxide and oxide/metal interfaces. The low-contact-resistance metal/metal interfaces in a reference or sense layer structure are in-situ formed in a high-vacuum deposition module of a sputtering system, without exposures to low vacuum in a transfer module and damages caused by a plasma treatment conducted in an etching module. The low-contact-resistance metal/oxide interface is formed by utilizing a thin Co—Fe—B reference layer and a thick Co—Fe reference layer to reduce boron diffusion and segregation caused by annealing. The low-contact-resistance oxide/metal interface is formed by replacing a Co—Fe—B sense layer with a Co-rich Co—Fe sense layer to eliminate boron diffusion and segregation caused by annealing. With the low-contact-resistance metal/metal, metal/oxide and oxide/metal interfaces, the TMR read sensor exhibits a junction resistance-area product of below 0.6 Ω-μm², while maintaining a low ferromagnetic coupling field and a high TMR coefficient.

These and other features and advantages of the invention will be apparent upon reading of the following detailed description of embodiments taken in conjunction with the figures in which like reference numerals indicate like elements throughout.

### BRIEF DESCRIPTION OF THE DRAWINGS

For a fuller understanding of the nature and advantages of the invention, as well as the preferred mode of use, reference should be made to the following detailed description read in conjunction with the accompanying drawings which are not to scale.

FIG. 1 is a schematic illustration of a magnetic disk drive in which the invention is embodied;

FIG. 2 is an ABS schematic view of a read head in accordance with a prior art;

FIG. 3 is an ABS schematic view of a read sensor in accordance with the invention;

FIG. 4 is a chart showing easy-axis magnetic responses of TMR read sensors with and without a plasma treatment after annealing for 5 hours at 280° C.;

FIG. 5 is a chart showing δ_{MgOx} versus R_{J}A_{J} for TMR read sensors with and without a plasma treatment after annealing for 5 hours at 280° C.;

FIG. 6 is a chart showing R_{J}A_{J} versus H_{F} for TMR read sensors with and without a plasma treatment after annealing for 5 hours at 280° C.;

FIG. 7 is a chart showing R_{J}A_{J} versus ΔR_{T}/R_{J} for TMR read sensors with and without a plasma treatment after annealing for 5 hours at 280° C.;

FIG. 8 is a chart showing easy-axis magnetic responses of TMR read sensors with Co—Fe—B and Co-rich Co—Fe sense layers after annealing for 5 hours at 280° C.;

FIG. 9 is a chart showing R_{J}A_{J} versus H_{F} for TMR read sensors with Co—Fe—B and Co-rich Co—Fe sense layers after annealing for 5 hours at 280° C.;

FIG. 10 is a chart showing R_{J}A_{J} versus ΔR_{T}/R_{J} for TMR read sensors with Co—Fe—B and Co-rich Co—Fe sense layers after annealing for 5 hours at 280° C.;

FIG. 11 is a chart showing R_{J}A_{J} versus H_{F} for TMR read sensors with ex-situ and in-situ metal/oxide/metal interfaces after annealing for 5 hours at 280° C.; and

FIG. 12 is a chart showing R_{J}A_{J} versus ΔR_{T}/R_{J} for TMR read sensors with ex-situ and in-situ metal/oxide/metal interfaces after annealing for 5 hours at 280° C.

Table 1 is a table listing H_{F}, R_{J}A_{J}, ΔR_{T}/R_{J} and FoM for TMR read sensors without a plasma treatment and with Co—Fe—B and Co—Fe reference layers of various thicknesses;

Table 2 is a table listing H_{F}, R_{J}A_{J}, ΔR_{T}/R_{J} and FoM for TMR read sensors without a plasma treatment and with Co—Fe and Co—Fe—B sense layers of various thicknesses; and

Table 3 is a table listing various methods of attaining low-contact-resistance metal/metal, metal/oxide and oxide/metal interfaces in accordance with the invention, and their evaluation based on Δδ_{MgOx}^{N}, ΔH_{F}^{N} and ΔFoM^{N}.

### DETAILED DESCRIPTION OF THE EMBODIMENTS

The following description is of the best embodiments presently contemplated for carrying out the invention. This description is made for the purpose of illustrating general principles of the invention and is not meant to limit inventive concepts claimed herein.

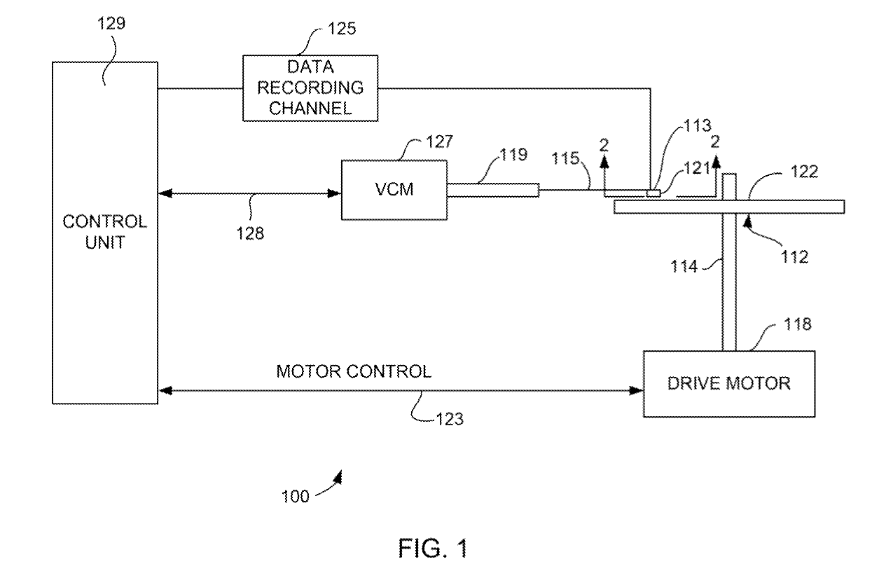

Referring now to FIG. 1, there is shown a magnetic disk drive 100 embodying the invention. As shown in FIG. 1, at least one rotatable magnetic disk 112 is supported on a spindle 114 and rotated by a disk drive motor 118. Magnetic recording on each magnetic disk is performed at annular patterns of concentric data tracks (not shown) on the magnetic disk 112.

At least one slider 113 is positioned near the magnetic disk 112, each slider 113 supporting one assembly of write and read heads 121. As the magnetic disk 112 rotates, the slider 113 moves radially in and out over the disk surface 122 so that the assembly of write and read heads 121 may access different data tracks on the magnetic disk 112. Each slider 113 is mounted on a suspension arm 115 that is supported by an actuator 119. The suspension arm 115 provides a slight spring force which biases the slider 113 against the disk surface 122. Each actuator 119 is attached to an actuator means 127 that may be a voice coil motor (VCM). The VCM comprises a coil movable within a fixed magnetic field, the direction and speed of the coil movements being controlled by the motor current signals supplied by a control unit 129.

During operation of the magnetic disk drive 100, the rotation of the magnetic disk 112 generates an air bearing between the slider 113 and the disk surface 122 which exerts an upward force or lift on the slider 113. The air bearing thus counter-balances the slight spring force of the suspension arm 115 and supports the slider 113 off and slightly above the disk surface 122 by a small, substantially constant spacing during sensor operation.

The various components of the magnetic disk drive 100 are controlled in operation by control signals generated by the control unit 129, such as access control and internal clock signals. Typically, the control unit 129 comprises logic control circuits, storage means and a microprocessor. The control unit 129 generates control signals to control various system operations such as drive motor control signals on line 123 and head position and seek control signals on line 128. The control signals on line 128 provide the desired current profiles to optimally move and position the slider 113 to the desired data track on the magnetic disk 112. Write and read signals are communicated to and from the assembly of write and read heads 121 by way of a recording channel 125.

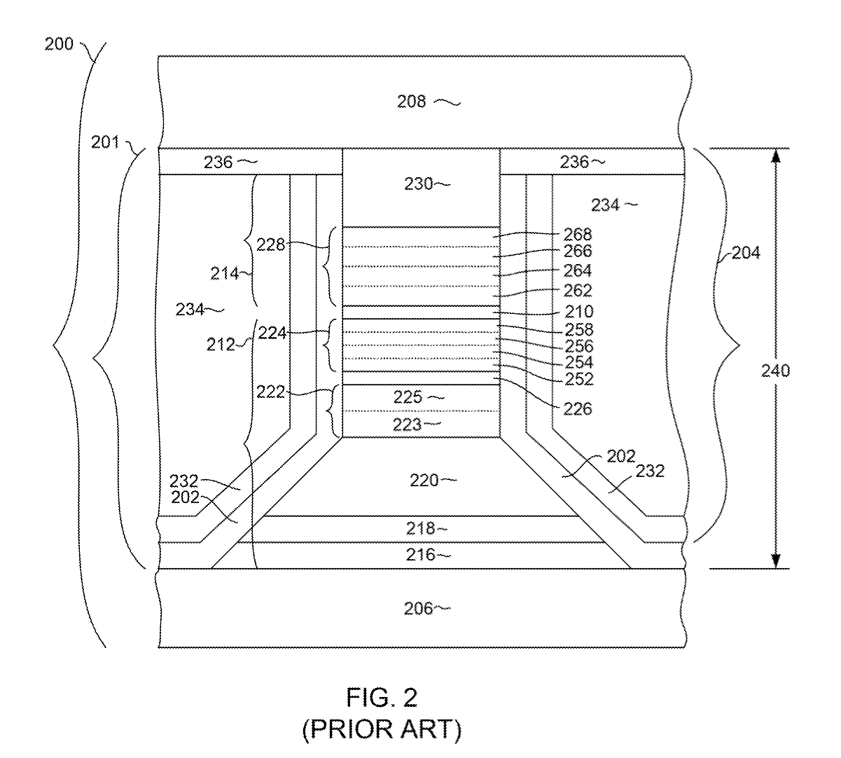

FIG. 2 shows a read head 200 in accordance with the prior art, where a tunneling magnetoresistance (TMR) read sensor 201 is electrically connected with lower and upper ferromagnetic shields 206, 208 to allow a sense current to flow in a direction perpendicular to planes of the TMR read sensor 201, but is electrically insulated by insulation layers 202 from longitudinal bias stacks 204 in two side regions to prevent the sense current from shunting through the two side regions.

The TMR read sensor 201 includes an electrically insulating MgO_{X} barrier layer 210 sandwiched between lower and upper sensor stacks 212, 214. The MgO_{X} barrier layer 210 is formed of a 0.1 nm thick oxygen-doped Mg (Mg—O) film, a 0.6 nm thick oxide (MgO) film, and another 0.1 nm thick oxygen-doped Mg (Mg—O) film.

The lower sensor stack 212 comprises a buffer layer 216 formed of a 2 nm thick nonmagnetic Ta film, a seed layer 218 formed of a 2 nm thick nonmagnetic Ru film, a pinning layer 220 formed of a 6 nm thick antiferromagnetic 23.2Ir-76.8Mn (composition in atomic percent) film, a keeper layer structure 222, an antiparallel-coupling layer 226 formed of a 0.4 nm thick nonmagnetic Ru film, and a reference layer structure 224. The keeper layer structure 222 comprises a first keeper layer 223 formed of a 1.8 nm thick ferromagnetic 72.5Co-27.5Fe film and a second keeper layer 225 formed of a 0.4 nm thick ferromagnetic Co film. The thicknesses of the first keeper layer 223 and the second keeper layer 225 are selected to attain a total saturation moment of 0.32 memu/cm² (corresponding to that of a 4.6 nm thick ferromagnetic 88Ni-12Fe film sandwiched between two Cu films). The reference layer structure 224 comprises a first reference layer 252 formed of a 0.4 nm thick ferromagnetic Co film, a second reference layer 254 formed of a 0.4 nm thick ferromagnetic 75.5Co-24.5Hf film, a third reference layer 256 formed of a 1.2 nm thick ferromagnetic 65.5Co-19.9Fe-14.6B film, and a fourth reference layer 258 formed of a 0.4 nm thick ferromagnetic 46.8Co-53.2 Fe film. The thicknesses of the first reference layer 252, the second reference layer 254, the third reference layer 256 and the fourth reference layer 258 are selected to attain a total saturation moment of 0.30 memu/cm² (corresponding to that of a 4.3 nm thick ferromagnetic 88Ni-12Fe film sandwiched between two Cu films).

The upper sensor stack 214 comprises a sense layer structure 228 and a cap layer structure 230. The sense layer structure 228 comprises a first sense layer 262 formed of a 0.4 nm thick ferromagnetic 46.8Co-53.2Fe film, a second sense layer 264 formed of a 1.6 nm thick ferromagnetic 79.3Co-4.0Fe-16.7B film, a third sense layer 266 formed of a 1.2 nm thick ferromagnetic 75.5Co-24.5Hf film, and a fourth sense layer 268 formed of a 5.6 nm thick ferromagnetic 96Ni-4Fe film. The thicknesses of the first sense layer 262, the second sense layer 264, the third sense layer 266 and the fourth sense layer 268 are selected to attain a total saturation moment of 0.56 memu/cm² (corresponding to that of a 8 nm thick ferromagnetic 88Ni-12Fe film sandwiched between two Cu films). The cap layer structure 230 comprises a first cap layer formed of a 1 nm thick nonmagnetic Ru film, a second cap layer formed of a 1 nm thick nonmagnetic Ta film, and a third cap layer formed of a 4 nm thick nonmagnetic Ru film.

A typical insulation layer 202 in each side region is formed of a 2 nm thick nonmagnetic, amorphous Al₂O₃ film. A typical longitudinal bias stack 204 in each side region comprises a seed layer 232 formed of a 4 nm thick nonmagnetic Cr film, a longitudinal bias layer 234 formed of a 25.6 nm thick hard-magnetic 82Co-18Pt film, and a cap layer 236 formed of a 10 nm thick nonmagnetic Cr film. The thickness of the Co—Pt longitudinal layer 234 is selected to attain a remnant moment of 2.24 memu/cm² (corresponding to that of a 32 nm thick ferromagnetic 88Ni-12Fe film sandwiched between two Cu films).

In the fabrication process of the read head 200, the TMR read sensor 201 is deposited on a wafer with a lower shield 206 formed of a 1 μm thick ferromagnetic 80Ni-20Fe film in various deposition modules of a sputtering system, and is annealed in a magnetic field of 50,000 Oe for 5 hours at 280° C. in a high-vacuum oven. In the deposition process of the TMR read sensor 201, the wafer is frequently transferred through a transfer module not only to the various deposition modules, but also to an etching module to apply a plasma treatment to a metal/metal interface in the reference layer structure 224. The plasma treatment mildly etches the metal/metal interface in the reference layer structure 224 for 72 seconds at a target power of 20 W, thereby smoothening the surface of the lower sensor stack 212 and facilitating the MgO_{X} barrier layer 210 to grow thereon with less waviness.

The plasma treatment may be applied to the Co reference layer 252 or the Co—Hf reference layer 254. However, its mild etching effect may penetrate downwards into the adjacent Ru antiparallel coupling layer 226, thus deteriorating the antiparallel coupling strength. Alternatively, the plasma treatment may be applied to the Co—Fe—B reference layer 256. However, its mild etching effect may slightly damage the metal/metal interface between the Co—Fe—B reference 256 and the Co—Fe reference layer 258, thus deteriorating the tunneling effect that relies on scattering of conduction electrons in the Co—Fe—B reference layer 256 and the Co—Fe reference layer 258. Alternatively, the plasma treatment may be applied to the Co—Fe reference layer 258. While its smoothening effect may be maximized, its mild etching effect may slightly damage the metal/oxide interface where coherent scattering of conduction electrons induces the most significant tunneling effect. It is thus recommended to apply the plasma treatment to the Co—Fe—B reference layer 256 and slightly reduce its thickness from 1.32 to 1.2 nm to alleviate concerns on the deteriorations of the antiparallel coupling strength and the tunneling effect.

The TMR read sensor 201 is patterned in a photolithographic process to produce sensor front and rear edges, and then patterned again in another photographic process to produce sensor tails at the two side regions. The Al₂O₃ insulation layer 202 and the longitudinal bias stack 204 are then deposited into the two side regions. The photoresist is then removed and a chemical-mechanical-polishing process is conducted. The TMR read sensor 201, the Al₂O₃ insulation layer 202, and the longitudinal bias stack 204 are then covered by the upper shield 208 also formed of a 1 μm thick ferromagnetic 80Ni-20Fe film, and by a gap formed of a 100 nm thick ferromagnetic Al₂O₃ film. A read gap 240 is defined by the thickness of the TMR read sensor 201, or a distance between the lower shield 206 and the upper shield 208. After completing the read head fabrication process, the write head fabrication process starts.

The keeper layer structure 222, the antiparallel-coupling layer 226 and the reference layer structure 224 form a flux closure where four magnetic interactions occur. First, antiferromagnetic/ferromagnetic coupling occurs between the pinning layer 220 and the keeper layer structure 222, thus increasing the easy-axis coercivity (H_{C}) of the keeper layer structure 222 and inducing a unidirectional anisotropy field (H_{UA}). Second, ferromagnetic/ferromagnetic coupling occurs across the antiparallel-coupling layer 226 and between the keeper layer structure 222 and the reference layer structure 224, thus inducing a bidirectional anisotropy field (H_{BA}). Third, ferromagnetic/ferromagnetic coupling also occurs across the barrier layer 210 and between the reference structure 224 and the sense layer structure 228, thus increasing the easy-axis coercivity (H_{CE}) of the sense layer structure 228 and inducing a ferromagnetic-coupling field (H_{F}). Fourth, magnetostatic interaction occurs in the sense layer structure 228 due to stray fields that stem from the net magnetization of the keeper layer structure 222 and the reference layer structure 224, thus inducing a demagnetizing field (H_{D}). To ensure proper sensor operation, H_{UA} and H_{BA} must be high enough to rigidly pin the magnetizations of the keeper layer structure 222 and the reference layer structure 224 in opposite transverse directions perpendicular to the ABS, while H_{F} and H_{D} must be small and balance with each other to orient the magnetization of the sense layer structure 228 in a longitudinal direction parallel to the ABS.

When a sense current flows in a direction perpendicular to interfaces of the TMR read sensor 201, the TMR read sensor 201 acts as a series circuit. Its extrinsic junction resistance (R_{J}), that depends on a sensor geometry, is a sum of R_{M}, R_{MgOx} and R_{C}, where R_{M} is the total resistance of all the metallic layers, R_{MgOx} is the resistance of the MgO_{X} barrier layer 210, and R_{C} is the total contact resistance of all the interfaces. Since the resistivity of the MgO_{X} barrier layer 210 (ρ_{MgOx}) is higher than 1×10⁵ μΩ-cm while resistivities of all the metallic layers are lower than 200 μΩ-cm, the MgO_{X} barrier layer 210 acts as the highest-resistance path in the series circuit. When the thickness of the MgO_{X} barrier layer 210 (δ_{MgOx}) is large enough to exhibit a significantly high R_{MgOx}, R_{M} is negligible and R_{J} is thus the sum of R_{MgOx} and R_{C}. In other words, the intrinsic area resistance of the TMR read sensor 201 (R_{J}A_{J}, where A_{J} is a junction area) is a sum of ρ_{MgOx} δ_{MgOx} and R_{C} A_{J}.

When the sense current quantum-jumps across the MgO_{X} barrier layer 210 and a magnetic field rotates the magnetization of the sense layer structure 228 from the same direction as that of the reference layer structure 224 to an opposite direction, scattering of conduction electrons at lower and upper interfaces of the MgO_{X} barrier layer 210 induces the tunneling effect and causes an increase in the resistance from R_{J} to R_{J}+ΔR_{T}. The strength of this tunneling effect can be characterized by a TMR coefficient (ΔR_{T}/R_{J}).

It is desirable to attain a high ΔR_{T}/R_{J} at a low R_{J}A_{J} for ensuring high read signals from a miniaturized TMR read sensor 201 without high electronic noises and electrostatic discharges. The low R_{J}A_{J} requires low ρ_{MgOx} δ_{MgOx} or R_{C}A_{J}. ρ_{MgOx} has reached an intrinsic value after optimizing the deposition of the MgO_{X} barrier layer 210 to ensure no residual Mg atoms and no excessive oxygen atoms. δ_{MgOx} has reached a minimal value, below which more pinholes will deteriorate the tunneling effect. A_{J} is fixed after defining a track width in a photolithographic process and a stripe height in a chemical-mechanical-polishing process. R_{C} thus remains as the only parameter ignored in any methods of reducing R_{J}A_{J} in the prior art. In details, R_{C} is a sum of R_{C1}, R_{C2} and R_{C3}, where R_{C1} is the total contact resistance of all the metal/metal interfaces, R_{C2} is the contact resistance of the metal/oxide interface, and R_{C3} is the contact resistance of the oxide/metal interface.

In the prior art, the Co—Fe reference layer 258 with a thickness of as small as 0.4 nm separates the Co—Fe—B reference layer 256 with a thickness of as large as 1.2 nm from the MgO_{X} barrier layer 210. The thin Co—Fe reference layer 258 acts as a diffusion barrier layer to reduce boron diffusion through the metal/metal interface and boron segregation at the metal/oxide interface, thereby decreasing R_{C1} and R_{C2}, respectively.

In the prior art, the Co—Fe sense layer 262 with a thickness of as small as 0.4 nm also separates the Co—Fe—B sense layer 264 with a thickness of as large as 2.0 nm from the MgO_{X} barrier layer 210. The thin Co—Fe sense layer 262 also acts as a diffusion barrier layer to reduce boron diffusion through the metal/metal interface and boron segregation at the oxide/metal interface, thereby decreasing R_{C1} and R_{C3}, respectively.

In spite of the uses of the thin Co—Fe reference layer 258 and the thin Co—Fe sense layer 262 as diffusion barrier layers, the TMR read sensor 201 can exhibit ΔR_{T}/R_{J} of as high as 72% at R_{J}A_{J} of 0.68 Ω-μm² after annealing for 5 hours at 280° C. This strong tunneling effect originates not only from a transformation in the Co—Fe—B reference layer 256 and in the Co—Fe—B sense layer 264 from amorphous to polycrystalline phases after annealing, but also from the maintenance of a Co—Fe—B(001)[110]//MgO(001)[100]//Co—Fe—B(001)[110] epitaxial relationship across the thin Co—Fe reference layer 258 and the thin Co—Fe sense layer 262. The phase transformation and the epitaxial relationship ensure coherent scattering of conduction electrons at the MgO_{X} barrier layer 210, thereby inducing the strong tunneling effect.

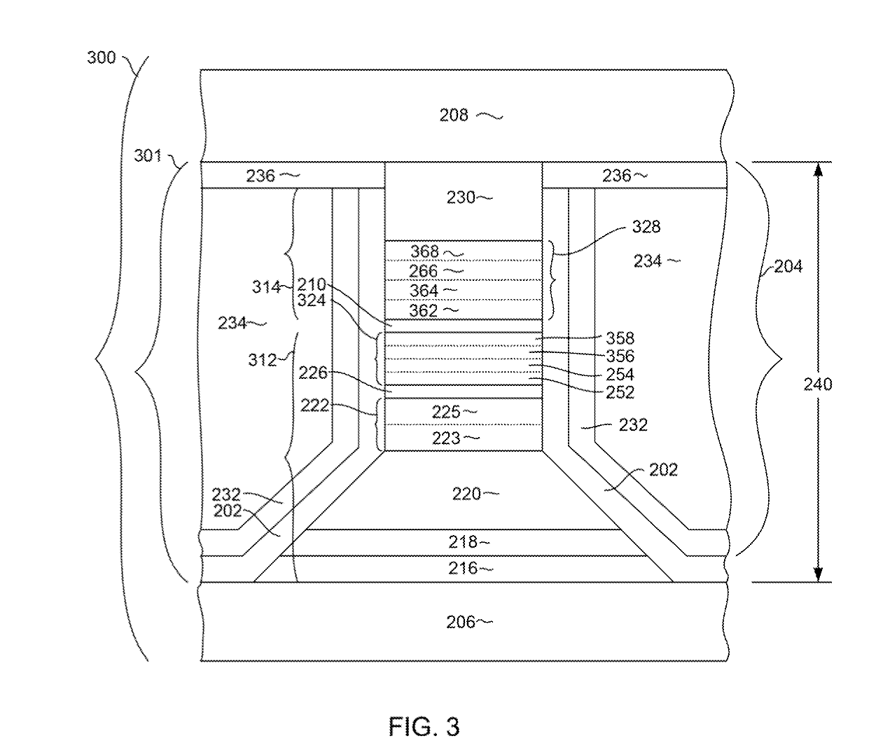

In the invention, methods of further decreasing R_{C1}, R_{C2} and R_{C3} are proposed, as described below. FIG. 3 shows a read head 300 in accordance with the invention. The read head 300 is basically identical to the read head 200, except that the reference layer structure 324 of the lower sensor stack 312 and the sense layer structure 328 of the upper sensor stack 314 in the TMR read sensor 301 are formed of different reference and sense layers, respectively, with methods of further decreasing R_{C1}, R_{C2} and R_{C3}.

The reference layer structure 324 comprises a first reference layer 252 formed of a 0.2-0.6 nm (or 0.4 nm) thick ferromagnetic Co film, a second reference layer 254 formed of a 0.2-0.6 nm (or 0.4 nm) thick ferromagnetic 75.5Co-24.5Hf film, a third reference layer 356 formed of a 0.4-1.0 nm (or 0.6 nm) thick ferromagnetic 65.5Co-19.9Fe-14.6B film, and a fourth reference layer 358 formed of a 0.4-1.2 nm (or 0.8 nm) thick ferromagnetic 46.8Co-53.2 Fe film. The thickness of the Co—Fe—B reference layer 356 is minimized while that of the Co—Fe reference layer 358 is maximized correspondingly to attain a total saturation moment of 0.30 memu/cm² (corresponding to that of a 4.3 nm thick ferromagnetic 88Ni-12Fe film sandwiched between two Cu films), and to reduce boron diffusion through the metal/metal interface and boron segregation at the metal/oxide interface, thereby decreasing R_{C1} and R_{C2}, respectively.

While exact atomic ratios of the layers 252, 254, 356, 358 have been described above, this by way of providing a best mode contemplated by the inventor. More generally the atomic ratios of the layers 252, 254, 356, 358 can be described as follows. The layer 254 can be 66-86 atomic percent Co and 14-34 atomic percent Hf. The layer 356 can be 55-75 atomic percent Co, 10-30 atomic percent Fe and 5-25 atomic percent B. The layer 358 can be 37 to 57 atomic percent Co and 43 to 63 atomic percent Fe.

The sense layer structure 328 comprises a first sense layer 362 formed of a 0.4-1.2 nm (or 0.8 nm) thick ferromagnetic 46.8Co-53.2Fe film, a second sense layer 364 formed of a 0.4-1.2 nm (or 1.2 nm) thick ferromagnetic 79.3Co-4.0Fe-16.7B film, a third sense layer 266 formed of a 0.6-1.8 nm (or 1.2 nm) thick ferromagnetic 75.5Co-24.5Hf film, and a fourth sense layer 368 formed of a 2.4-7.2 nm (or 4.8 nm) thick ferromagnetic 96Ni-4Fe film. The thickness of the Co—Fe sense layer 362 is maximized while that of the Co—Fe—B sense layer 358 is minimized correspondingly to attain a total saturation moment of 0.56 memu/cm² (corresponding to that of a 8.0 nm thick ferromagnetic 88Ni-12Fe film sandwiched between two Cu films), and to reduce boron diffusion through the metal/metal interface and boron segregation at the oxide/metal interface, thereby decreasing R_{C1} and R_{C3}, respectively.

While exact atomic ratios of the layers 362, 364, 266, 368 have been described above, this by way of providing a best mode contemplated by the inventor. More generally the atomic ratios of the layers 362, 364, 266, 368 can be described as follows. The layer 362 can be 37-57 atomic percent Co and 43-63 atomic percent Fe. The layer 364 can be 69-89 atomic percent Co, 0-14 atomic percent Fe and 7-27 atomic percent B. The layer 266 can be 66-86 atomic percent co and 14-34 atomic percent Hf. The layer 368 can be 86-100 atomic percent Ni and 0-14 atomic percent Fe.

Alternatively, the sense layer structure 328 comprises a first sense layer 362 formed of a 0.4-1.2 (or 0.8 nm) thick ferromagnetic 46.8Co-53.2Fe film, a second sense layer 364 formed of a 1.0-3.0 nm (or 2.0 nm) thick ferromagnetic 90.4Co-9.6Fe film, a third sense layer 266 formed of a 0.6-1.8 nm (or 1.2 nm) thick ferromagnetic 75.5Co-24.5Hf film, and a fourth sense layer 368 formed of a 2.4-7.2 nm (or 2.8 nm) thick ferromagnetic 96Ni-4Fe film. The thickness of the Co-rich Co—Fe sense layer 364 is maximized while that of the Ni—Fe sense layer 368 is minimized correspondingly to attain a total saturation moment of 0.56 memu/cm² (corresponding to that of a 8.0 nm thick ferromagnetic 88Ni-12Fe film sandwiched between two Cu films). The Co—Fe—B sense layer is not used at all to completely eliminate boron diffusion through the metal/metal interface and boron segregation at the oxide/metal interface, thereby substantially decreasing R_{C1} and R_{C3}, respectively.

While exact atomic ratios of the layers 362, 364, 266, 368 in this above described alternative embodiment have been described as exact atomic ratios, this by way of providing a best mode contemplated by the inventor. More generally the atomic ratios of the layers 362, 364, 266, 368 in this alternative embodiment can be described as follows. The layer 362 can be 37-57 atomic percent Co and 43-63 atomic percent Fe. The layer 364 can be 80-100 atomic percent Co and 0-20 atomic percent Fe. The layer 266 can be 66-86 atomic percent Co and 14-34 atomic percent Hf. The layer 368 can be 86 to 100 atomic percent Ni and 0.14 atomic percent Fe.

In a method of further decreasing R_{C1} in accordance with the invention, the reference layer structure 324 is in-situ formed without a plasma treatment. In other words, the Co reference layer 252, the Co—Hf reference layer 254, the Co—Fe—B reference layer 256 and the Co—Fe reference layer 258 are sequentially in-situ deposited on a wafer in a deposition module of a sputtering system. Without transfers through a transfer module to different deposition modules for depositions and to an etching module for the plasma treatment, low-R_{C1} metal/metal interfaces are immediately in-situ formed in the reference layer structure 324. It should be noted that the term “in-situ” is strictly defined in the invention by processes conducted only in a deposition module, without exposures to other vacuum in different transfer, deposition and etching modules, instead of to air in general. To immediately in-situ form more low-R_{C1} metal/metal interfaces in the lower sensor stack 312 the seed layer 218, the pinning layer 220, the keeper layer structure 222 and the antiparallel coupling layer 226 may also be sequentially in-situ deposited in the same deposition module. However, it is difficult to conduct in this way since in general there are only five or six targets in one deposition module, and it is less crucial since these layers do not affect the tunneling.

In another method of further decreasing R_{C1} in accordance with the invention, the sense layer structure 328 is also in-situ formed. In other words, the Fe-rich Co—Fe sense layer 362, the Co—Fe—B or Co-rich Co—Fe sense layer 364, the Co—Hf sense layer 266 and the Ni—Fe sense layer 368 are sequentially in-situ deposited on a wafer in a deposition module of a sputtering system. Without transfers through a transfer module to different deposition modules for depositions, low-R_{C1} metal/metal interfaces are immediately in-situ formed in the sense layer structure 328. To immediately in-situ form more low-R_{C1} metal/metal interfaces in the upper sensor stack 314, the cap layer structure 230 may also be in-situ deposited in the same deposition module. However, it is difficult to conduct in this way since in general there are only five or six targets in one deposition module, and it is less crucial since these layers do not affect the tunneling.

In a method of further decreasing R_{C2} and R_{C3} in accordance with the invention, the Co—Fe reference layer 358, the MgO_{X} barrier layer 210 and the Fe-rich Co—Fe sense layer 362 are also sequentially in-situ deposited on a wafer in a deposition module of a sputtering system. Without transfers through a transfer module to different deposition modules for depositions, low-R_{C2} metal/oxide and low-R_{C3} oxide/metal interfaces are immediately in-situ formed.

The elimination of the plasma treatment leads to substantial decreases in R_{C1} and R_{J}A_{J}, as described below. The TMR read sensors with and without the plasma treatment are deposited on bare glass substrates and wafers. The TMR read sensor with the plasma treatment comprises Ta(2)/Ru(2)/Ir—Mn(6)/Co—Fe(1.8)/Co(0.4)/Ru(0.4)/Co(0.4)/Co—Hf(0.4)/Co—Fe—B(1.2)/Co—Fe(0.4)/MgO_{X}/Co—Fe(0.4)/Co—Fe—B(1.6)/Co—Hf(1.2)/Ni—Fe(4.8)/Ru(1)/Ta(1)/Ru(4) films (thickness in nm). The Co—Fe—B reference layer is originally 1.32 nm thick, but becomes 1.2 nm thick after the plasma treatment. The TMR read sensor without the plasma treatment comprises identical multilayer films. The only difference is that the Co—Fe—B reference layer is originally 1.2 nm thick.

After annealing in a magnetic field of 50,000 Oe for 5 hours at 280° C. in a high-vacuum oven, the TMR read sensor deposited on the bare glass substrate is measured with a vibrating sample magnetometer to determine H_{CE} and H_{F}. The TMR read sensor deposited on the wafer with the lower shield 206 is coated with Cu(75)/Ru(12) top conducting leads (not shown), and is probed with a 12-point microprobe in a magnetic field of about 160 Oe. Measured data from any four of the microprobe are analyzed with a current-in-plane tunneling model to determine R_{J}A_{J} and ΔR_{T}/R_{J}.

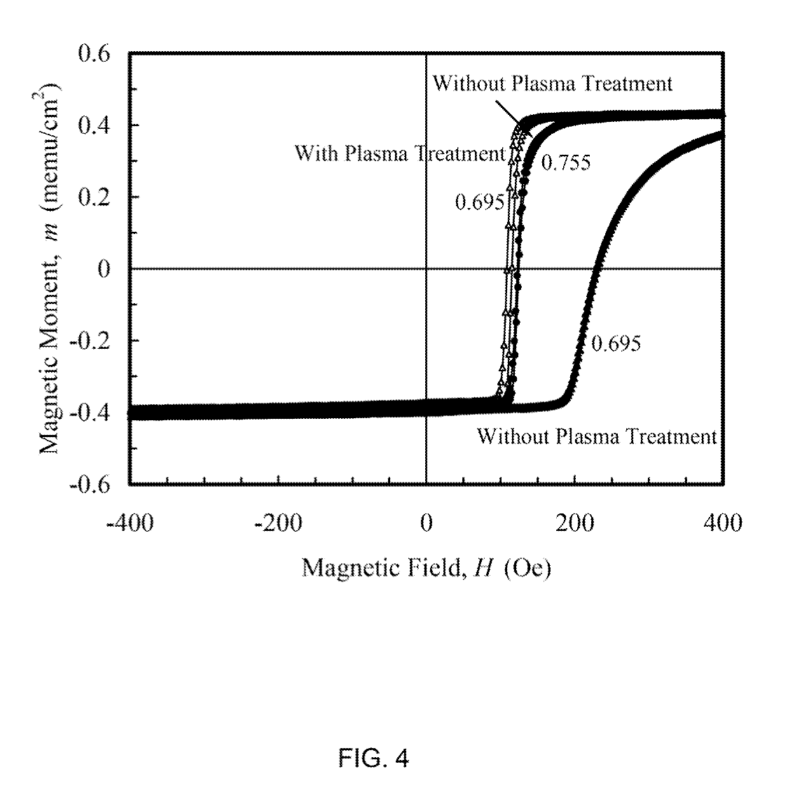

FIG. 4 shows easy-axis magnetic responses of the TMR read sensors with and without the plasma treatment after annealing for 5 hours at 280° C. The TMR read sensor with the plasma treatment exhibits H_{F} of 112.4 Oe when the MgO_{X} barrier layer 210 is 0.695 nm thick. The TMR read sensors without the plasma treatment exhibit H_{F} values of 229.9 and 124.1 Oe when the MgO_{X} barrier layers 210 are 0.695 and 0.755 nm thick, respectively. The elimination of the plasma treatment thus causes the TMR read sensor with a 0.695 nm thick MgO_{X} barrier layer 210 to substantially increase H_{F} from 112.4 to 229.9 Oe (by as large as 117.5 Oe). However, this substantial H_{F} increase requires an adjustment based on a fixed R_{J}A_{J}, as described below.

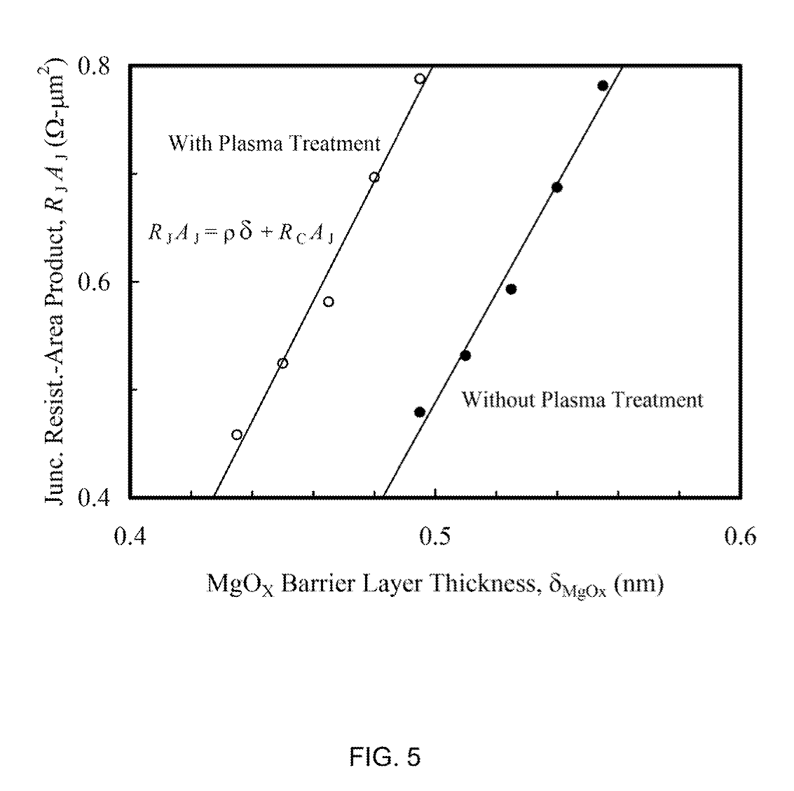

FIG. 5 shows δ_{MgOx} versus R_{J}A_{J} for the TMR read sensors with and without the plasma treatment after annealing for 5 hours at 280° C. R_{J}A_{J} increases nearly linearly with δ_{MgOx}, as predicted by R_{J}A_{J}=ρ_{MgOx}δ_{MgOx}+R_{C}A_{J}. The ρ_{MgOx} values for the TMR read sensors with and without the plasma treatment are calculated from slopes of two straight lines and found to be 5.54×10⁵ and 5.06×10⁵ μΩ-cm, respectively. By fixing ρ_{MgOx} δ_{MgOx}, R_{J}A_{J} varies with R_{C}A_{J}. For example, by eliminating the plasma treatment for the TMR read sensor with a 0.695 nm thick MgO_{X} barrier layer 210, R_{J}A_{J} decreases from 0.79 to 0.48 Ω-μm² (by as large as 0.31 Ω-μm²), indicating that R_{C}A_{J} also decreases by as large as 0.31 Ω-μm². This large R_{C}A_{J} decrease mainly originates from a lower R_{C1} attained after preventing the metal/metal interface between the Co—Fe—B reference 356 and the Co—Fe reference layer 358 from the slight damage caused by the plasma treatment. Therefore, to facilitate the TMR read sensor with even smaller δ_{MgOx} to exhibit a lower R_{C1}, the plasma treatment must be eliminated.

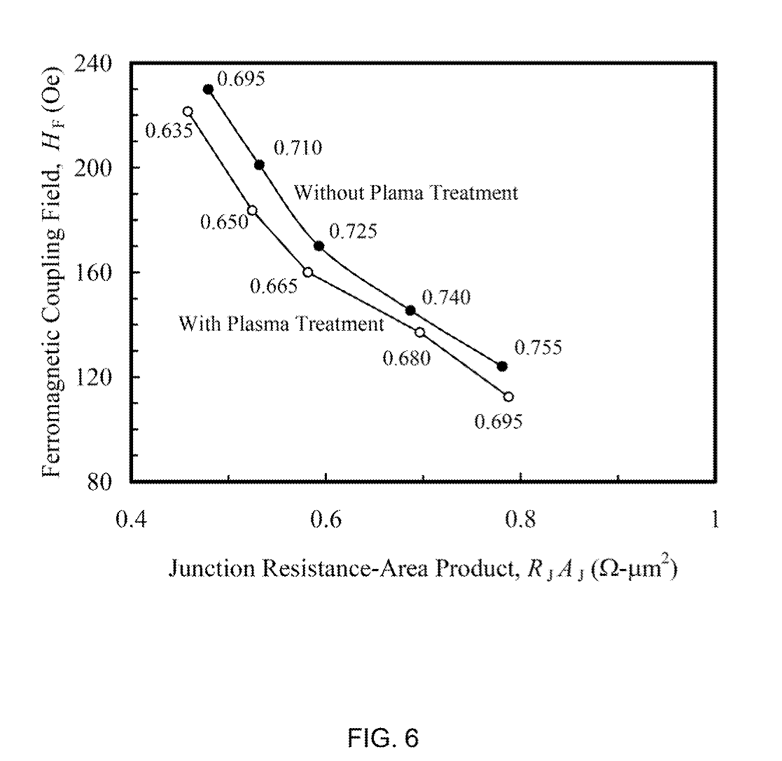

FIG. 6 shows R_{J}A_{J} versus H_{F} for the TMR read sensors with and without the plasma treatment after annealing for 5 hours at 280° C. R_{J}A_{J} increases with δ_{MgOx}, which is labeled in a unit of nm next to each symbol. For example, R_{J}A_{J} increases from 0.48 and 0.78 Ω-μm² as δ_{MgOx} increases from 0.695 to 0.755 nm for the TMR read sensor without the plasma treatment. Therefore, to attain R_{J}A_{J} comparable to that (0.79 Ω-μm²) of the TMR read sensor with the plasma treatment and a 0.695 nm thick MgO_{X} barrier layer 210, the elimination of the plasma treatment requires a δ_{MgOx} increase by as large as 0.06 nm. This substantial δ_{MgOx} increase is expected to reduce its pinhole density and thus improve its reliability.

In addition, H_{F} decreases sharply as R_{J}A_{J} increases. For example, H_{F} decreases sharply from 229.9 to 124.1 Oe as R_{J}A_{J} increases from 0.48 and 0.78 Ω-μm² for the TMR read sensor without the plasma treatment. Therefore, after attaining R_{J}A_{J} comparable to that (0.79 Ω-μm²) of the TMR read sensor with the plasma treatment and the 0.695 nm thick MgO_{X} barrier layer 210, the elimination of the plasma treatment causes an H_{F} increase from 112.4 to 124.1 Oe (by as small as 11.7 Oe). This small H_{F} decrease can also be realized by comparing two hysteresis loops as shown in FIG. 4, one for the TMR read sensor with the plasma treatment and the 0.695 nm thick MgO_{X} barrier layer 210, and the other for the TMR read sensor without the plasma treatment and with the 0.755 nm thick MgO_{X} barrier layer 210.

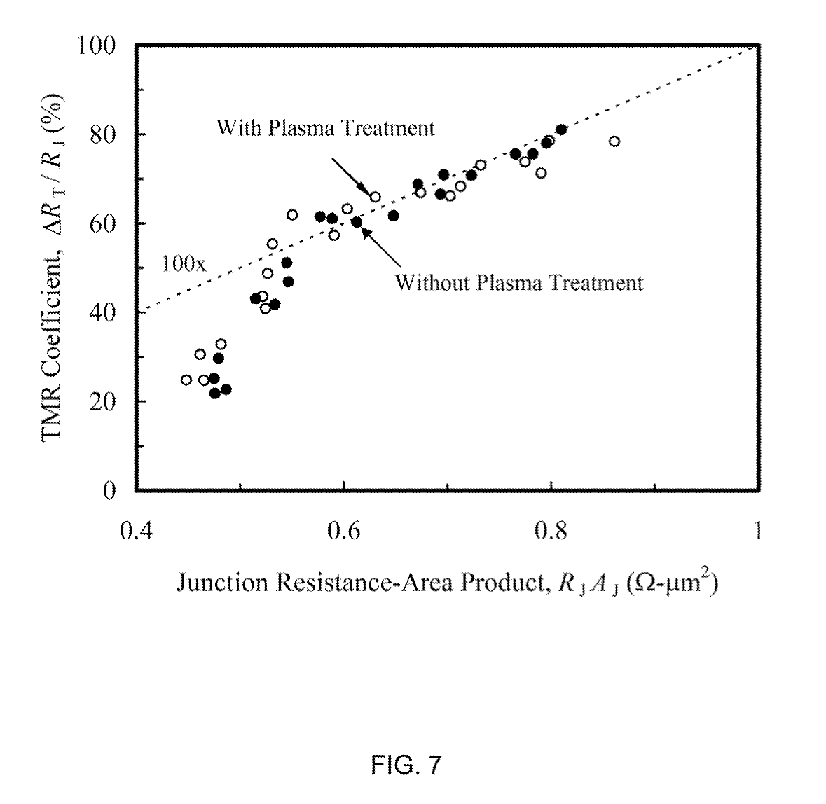

FIG. 7 shows R_{J}A_{J} versus ΔR_{T}/R_{J} for the TMR read sensors with and without the plasma treatment after annealing for 5 hours at 280° C. A ratio of ΔR_{T}/R_{J} to R_{J}A_{J} is defined as FoM, which is proportional to a read amplitude and is thus a figure of merit to quantify the tunneling effect by the read amplitude. Data points above a dash line labeled with FoM=100 thus indicate a strong tunneling effect. With the plasma treatment, ΔR_{T}/R_{J} reaches 60.8% at R_{J}A_{J} of 0.58 Ω-μm² (or FoM of 104.8). Without the plasma treatment, ΔR_{T}/R_{J} reaches 61.0% at R_{J}A_{J} of 0.59 Ω-μm² (or FoM of 103.4). After eliminating the plasma treatment, FoM appears nearly unchanged, but data distributions become tighter, indicating improved uniformity over the wafer. In addition, FoM is around 100 when R_{J}A_{J} exceeds 0.6 Ω-μm², but is lower than 100 when R_{J}A_{J} is less than 0.6 Ω-μm². It should be noted though that FoM at R_{J}A_{J} of less than 0.6 Ω-μm² is underestimated, since H_{F} exceeds 160 Oe, which is the maximum magnetic field in the 12-point microprobe.

In summary, FIGS. 4, 5, 6 and 7 suggest that a fair comparison must be conducted based on a fixed R_{J}A_{J} design. To conduct the fair comparison, δ_{MgOx}, H_{F}, and FoM are normalized for R_{J}A_{J}=0.6 Ω-μm² and defined as δ_{MgOx}^{N}, H_{F}^{N} and FoM^{N}, respectively. FIG. 5 reveals that the elimination of the plasma treatment causes an increase in δ_{MgOx}^{N} from 0.663 to 0.722 nm (by 0.059 nm). FIG. 6 reveals that the elimination of the plasma treatment causes an increase in H_{F}^{N} (which is calculated by assuming an inverse relationship between H_{F} and R_{J}A_{J} at R_{J}A_{J} of around 0.6 Ω-μm²) from 156.2 to 167.6 Oe (by 11.4 Oe). FIG. 7 reveals that the elimination of the plasma treatment causes a decrease in FoM^{N} (which is calculated by assuming a linear relationship between R_{J}A_{J} and ΔR_{T}/R_{J} at R_{J}A_{J} of around 0.6 Ω-μm²) from 104.0 to 102.4 (by 1.6). Since the MgO_{X} barrier layer 210 is preferably thick to ensure a low pinhole density and high reliability in an ongoing effort of exploring lower R_{J}A_{J}, it is proposed to eliminate the plasma treatment to form a low-R_{C1} metal/metal interface.

In order for the TMR read sensor 301 to exhibit an even lower R_{J}A_{J}, the metal/oxide interface at the reference layer structure 328 is preferably formed without boron diffusion and segregation. It is thus suggested in the invention to completely eliminate the Co—Fe—B reference layer 356 in the reference layer structure 328. However, the Co—Fe—B reference layer 356 with a thickness of at least 1.2 nm is needed to exhibit the desired tunneling effect in accordance with the prior art. It is speculated though that without the plasma treatment which may cause slight damages into the Co—Fe—B reference layer 356, a thinner Co—Fe—B reference layer 356 might function enough to exhibit the desired tunneling effect. In addition, a thicker Co—Fe reference layer 358 may be used to further suppress the boron diffusion and segregation at the metal/oxide interface.

Table 1 lists H_{F}, R_{J}A_{J}, ΔR_{T}/R_{J} and FoM for TMR read sensors 301 without the plasma treatment and with Co—Fe—B and Co—Fe reference layers of various thicknesses. The TMR read sensor 301 comprises Ta(2)/Ru(2)/Ir—Mn(6)/Co—Fe(1.8)/Co(0.4)/Ru(0.4)/Co(0.4)/Co—Hf(0.4)/Co—Fe—B/Co—Fe/MgO_{X}(0.74)/Co—Fe(0.4)/Co—Fe—B(2.0)/Co—Hf(1.2)/Ni—Fe(4.8)/Ru(1)/Ta(1)/Ru(4) films. To maintain the saturation moment of the reference layer structure 328 unchanged for a fair comparison, a 0.34 nm decrease in the thickness of the Co—Fe—B reference layer 356 with a saturation magnetization (M_{S}) of 1,018 emu/cm³ requires a 0.2 nm increase in that of the Co—Fe reference layer 358 with M_{S} of 1,734 emu/cm³. Therefore, when the Co—Fe—B reference layers are 1.2, 0.86, 0.52, 0.18 and 0 nm thick, the Co—Fe reference layers are 0.4, 0.6, 0.8, 1.0 and 1.1 nm, respectively. With the 1.2, 0.86, 0.52, 0.18 and 0 nm thick Co—Fe—B reference layers 356, the TMR read sensors 301 exhibit H_{F} values of 107.3 to 106.7, 109.5, 135.8 and 137.7 Oe, respectively, R_{J}A_{J} values of 0.73, 0.70, 0.66, 0.57 and 0.50 Ω-μm², respectively, and ΔR_{T}/R_{J} values of 80.0, 78.2, 71.4, 36.4 and 10.0%, respectively.

R_{J}A_{J} gradually decreases from 0.73 to 0.66 Ω-μm² as the thickness of the Co—Fe—B reference layer 356 decreases from 1.2 to 0.52 nm. The uses of a thinner Co—Fe—B reference layer 356 and a thicker Co—Fe reference layer 358 thus lead to less boron diffusion and segregation at the metal/oxide interface, thereby causing the R_{J}A_{J} decrease. Unexpectedly, H_{F} remains nearly unchanged as R_{J}A_{J} decreases from 0.73 to 0.66 Ω-μm², instead of increasing sharply as predicted from an inverse relationship between H_{F} and R_{J}A_{J}. The uses of a thinner Co—Fe—B reference layer 356 and a thicker Co—Fe reference layer 358 thus improve the surface flatness of the reference layer structure 328 due to less boron diffusion segregation at the metal/oxide interface, thereby maintaining the nearly identical H_{F} at lower R_{J}A_{J}. ΔR_{T}/R_{J} decreases from 80.0 to 71.4% as R_{J}A_{J} decreases from 0.73 to 0.66 Ω-μm². Since FoM remains nearly unchanged, the tunneling effect in fact remains nearly identical. It is thus confirmed that without the plasma treatment which may cause slight damages into the Co—Fe—B reference layer 356, the Co—Fe—B reference layer 356 can be as thin as 0.52 nm to act as a nucleus for inducing the desired tunneling effect.

In addition, R_{J}A_{J} sharply decreases to 0.50 Ω-μm² after eliminating the entire Co—Fe—B reference layer 356. It is thus concluded that without boron segregates containing boron, which block the scattering path at the metal/oxide interface, R_{C2} substantially decreases and thus R_{J}A_{J} reaches a minimal value. However, without the Co—Fe—B reference layer 356, the TMR read sensor exhibits ΔR_{T}/R_{J} of as low as 10.0%.

Table 1 thus suggests a decrease in the thickness of the Co—Fe—B reference layer from 1.2 to 0.6 nm, and an increase in that of the Co—Fe reference layer from 0.4 to 0.8 nm. For a TMR read sensor with a designed R_{J}A_{J} of 0.6 Ω-μm², δ_{MgOx}^{N} (calculated from FIG. 5) will increase from 0.734 to 0.748 nm (by 0.014 nm), H_{F}^{N} (calculated from Table 1) will decrease from 130.5 to 120.4 Oe (by 10.1 Oe), and FoM^{N} (calculated by assuming that FoM remains constant for R_{J}A_{J}÷0.6 Ω-μm²) will slightly decrease by 1.9.

TABLE 1

| Co—Fe—B | Co—Fe | | | | |
|---|---|---|---|---|---|
| Ref. Layer | Ref. Layer | H_{F} | R_{J} A_{J} | ΔR_{T}/R_{J} | FoM |
| (nm) | (nm) | (Oe) | (Ω-μm²) | (%) | (%) |
| 1.2 | 0.4 | 107.3 | 0.73 | 80.0 | 110.4 |
| 0.86 | 0.6 | 106.7 | 0.70 | 78.2 | 111.8 |
| 0.52 | 0.8 | 109.5 | 0.66 | 71.4 | 108.5 |
| 0.18 | 1 | 135.8 | 0.57 | 36.4 | 63.7 |
| 0 | 1.1 | 137.7 | 0.50 | 10.0 | 20.0 |

In order for the TMR read sensor 301 to exhibit an even lower R_{J}A_{J}, the oxide/metal interface at the sense layer structure 328 is preferably formed without boron diffusion and segregation caused by annealing. It is thus suggested in the invention to completely eliminate the Co—Fe—B sense layer 264 in the sense layer structure 328. However, the Co—Fe—B sense layer 264 with a thickness of at least 1.6 nm is generally used to exhibit the desired tunneling effect in accordance with the prior art. The feasibility of eliminating the Co—Fe—B sense layer 264 is described below.

Table 2 lists H_{F}, R_{J}A_{J}, ΔR_{T}/R_{J} and FoM for TMR read sensors 301 without the plasma treatment and with Co—Fe and Co—Fe—B sense layers of various thicknesses. The TMR read sensor 301 comprises Ta(2)/Ru(2)/Ir—Mn(6)/Co—Fe(1.8)/Co(0.4)/Ru(0.4)/Co(0.4)/Co—Hf(0.4)/Co—Fe—B(1.2)/Co—Fe(0.4)/MgO_{X}(0.74)/Co—Fe/Co—Fe—B/Co—Hf(1.2)/Ni—Fe(4.8)/Ru(1)/Ta(1)/Ru(4) films. To maintain the saturation moment of the sense layer structure 328 unchanged for a fair comparison, a 0.4 nm decrease in the thickness of the Co—Fe—B sense layer 364 with M_{S} of 868 emu/cm³ requires a 0.2 nm increase in that of the Co—Fe sense layer 362 with M_{S} of 1,734 emu/cm³. Therefore, when the Co—Fe—B sense layers are 2.0, 1.6, 1.2 and 0.8 nm thick, the Co—Fe sense layers are 0.4, 0.6, 0.8 and 1.0 nm, respectively. With the 2.0, 1.6, 1.2 and 0.8 nm thick Co—Fe—B sense layers, the TMR read sensors 301 exhibit H_{F} values of 103.5, 101.5, 98.8 and 96.8 Oe, respectively, R_{J}A_{J} values of 0.73, 0.74, 0.74 and 0.73 Ω-μm², respectively, and ΔR_{T}/R_{J} values of 79.4, 79.5, 78.4 and 71.7%, respectively.

H_{F}, R_{J}A_{J} and ΔR_{T}/R_{J} remain nearly unchanged as the thickness of the Co—Fe—B sense layer 364 decreases from 2.0 to 1.2 nm. The uses of a thicker Co—Fe sense layer 362 and a thinner Co—Fe—B sense layer 364 thus appear to function well in maintaining the strong tunneling effect. It is understood though that as the Co—Fe sense layer 362 is thicker than 1.0 nm and the Co—Fe—B sense layer 364 is thinner than 0.8 nm, the tunneling effect starts to deteriorate. This deterioration in fact originates from an insufficient scattering length (a sum of thicknesses of the Co—Fe sense layer 362 and the Co—Fe—B sense layer 364), instead of the use of the thinner Co—Fe—B sense layer 364.

Table 2 thus suggests an increase in the thickness of the Co—Fe sense layer from 0.4 to 0.8 nm, and a decrease in that of the Co—Fe—B sense layer from 2.0 to 1.2 nm. For a TMR read sensor with a designed R_{J}A_{J} of 0.6 Ω-μm², δ_{MgOx}^{N} will stay at 0.734 nm, H_{F}^{N} will decrease from 125.9 to 121.8 Oe (by 3.1 Oe), and FoM^{N} will decrease from 109.4 to 106.3 (by 3.1). In addition, the thickness of the sense layer structure 328 will decrease by 0.4 nm, and thus the read gap will also decrease by 0.4 nm.

A comparison between Tables 1 and 2 reveals different diffusion behaviors of boron atoms in the Co—Fe—B reference layer 356 and in the Co—Fe—B sense layer 364. It seems easy for boron atoms in the Co—Fe—B reference layer 356 of as thin as 0.52 nm to diffuse upwards through the Co—Fe reference layer 358 of as thick as 0.8 nm, but difficult for boron atoms in the Co—Fe—B sense layer 364 of as thick as 2.0 nm to diffuse downwards through the Co—Fe sense layer 362 of as thin as 0.4 nm.

TABLE 2

| Co—Fe | Co—Fe—B | | | | |
|---|---|---|---|---|---|
| Sense Layer | Sense Layer | H_{F} | R_{J} A_{J} | ΔR_{T}/R_{J} | |
| (nm) | (nm) | (Oe) | (Ω-μm²) | (%) | FoM |
| 0.4 | 2.0 | 103.5 | 0.73 | 79.4 | 109.4 |
| 0.6 | 1.6 | 101.5 | 0.74 | 79.5 | 107.9 |
| 0.8 | 1.2 | 98.8 | 0.74 | 78.4 | 106.3 |
| 1.0 | 0.8 | 96.8 | 0.73 | 71.7 | 98.6 |

To further explore the feasibility of eliminating the Co—Fe—B sense layer 264, the Co—Fe—B sense layer 264 is replaced by a new second sense layer 364 preferably formed of a ferromagnetic 90.4Co-9.6Fe film. To maintain the saturation moment of the sense layer structure 328 unchanged for a fair comparison, a 2.0 nm thick Co—Fe—B sense layer 364 with M_{S} of 868 emu/cm³ is replaced by a 0.9 nm thick Co-rich Co—Fe sense layer 364 with M_{S} of 1,442 emu/cm³.

The Co-rich Co—Fe sense layer 364 differs from the Fe-rich Co—Fe sense layer 362 in that its lower Fe content may lead to a more negative saturation magnetostriction (λ_{S}), and thus it can be thicker for extending the scattering length (a sum of thicknesses of the Fe-rich Co—Fe sense layer 362 and the Co-rich Co—Fe sense layer 364). To maintain the saturation moment of the sense layer structure 328 unchanged for a fair comparison, a 0.2 nm increase in the thickness of the Co-rich Co—Fe sense layer 364 with M_{S} of 1,442 emu/cm³ requires a 0.53 nm decrease in that of the Ni—Fe sense layer 368 with M_{S} of 543 emu/cm³.

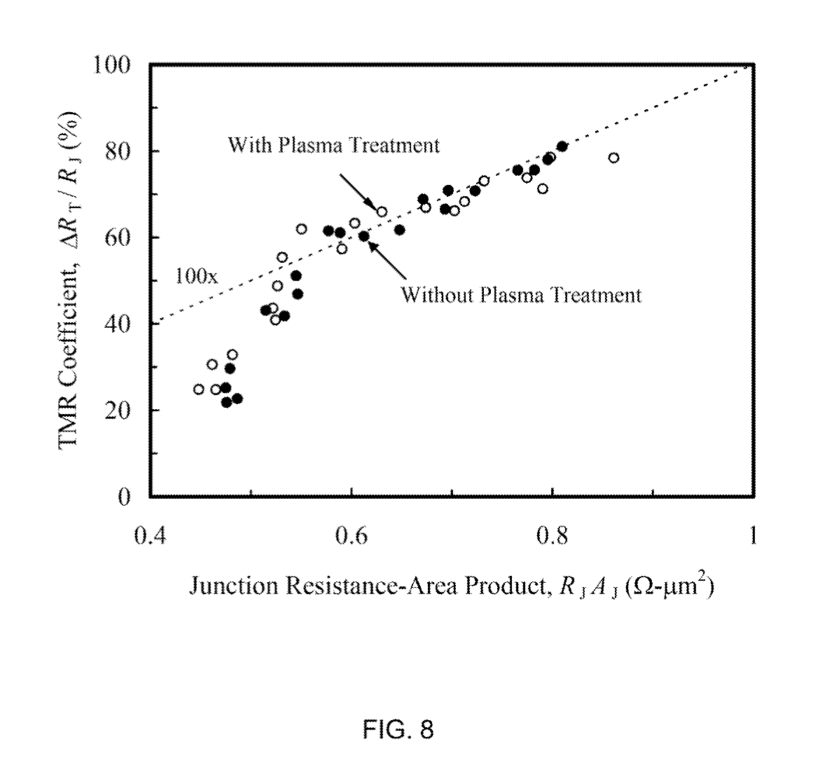

FIG. 8 shows easy-axis magnetic responses of TMR read sensors with the Co—Fe—B sense layer 264 and the Co-rich Co—Fe sense layer 364 after annealing for 5 hours at 280° C. The TMR read sensor 201 with the Co—Fe—B sense layer 264 comprises Ta(2)/Ru(2)/Ir—Mn(6)/Co—Fe(1.8)/Co(0.4)/Ru(0.4)/Co(0.4)/Co—Hf(0.4)/Co—Fe—B(1.2)/Co—Fe(0.4)/MgO_{X}(0.755)/Co—Fe(0.4)/Co—Fe—B(1.6)/Co—Hf(1.2)/Ni—Fe(5.6)/Ru(1)/Ta(1)/Ru(4) films. The TMR read sensor 301 with the Co-rich Co—Fe sense layer 364 comprises an identical sensor structure except that a 2.0 nm thick 90.4Co-9.6Fe sense layer 364 replaces the 1.6 nm thick Co—Fe—B sense layer 264, and the thickness of the Ni—Fe sense layer 268 decreases from 5.6 to 2.8 nm correspondingly to maintain an identical sense-layer saturation moment of 0.56 memu/cm² (corresponding to that of a 8.0 nm thick ferromagnetic 88Ni-12Fe film sandwiched between two Cu films). After replacing the Co—Fe—B sense layer 264 with the Co-rich Co—Fe sense layer 364, H_{F} decreases from 93.2 to 72.7 Oe (by 20.5 Oe). The elimination of boron diffusion and segregation at the oxide/metal interface is thus essential in reducing H_{F} substantially.

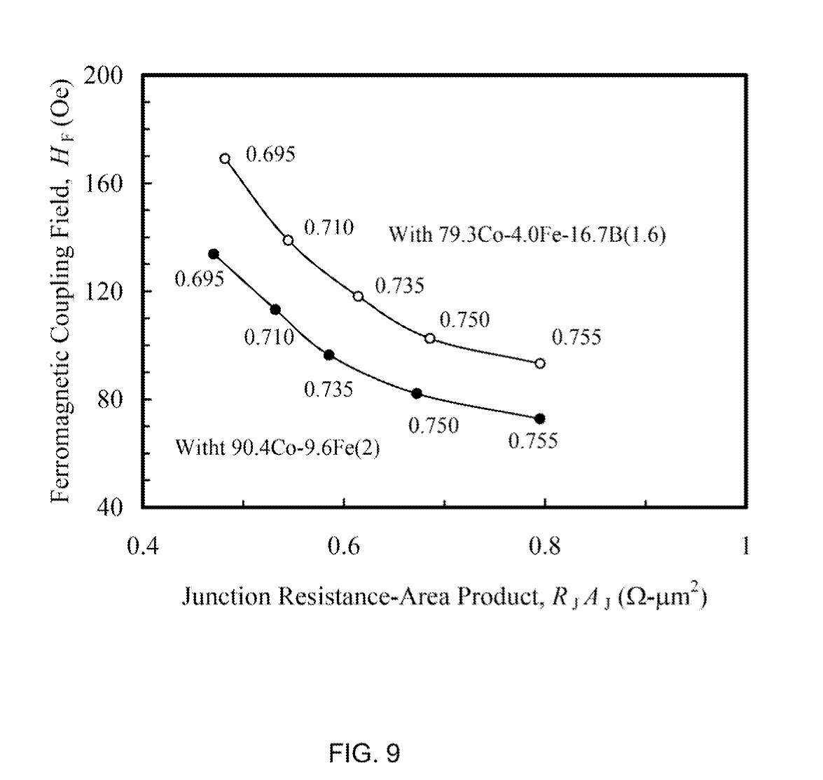

FIG. 9 shows R_{J}A_{J} versus H_{F} for TMR read sensors with a 1.6 nm thick Co—Fe—B sense layer 264 and a 2.0 nm thick Co-rich Co—Fe sense layer 364 after annealing for 5 hours at 280° C. The two types of the TMR read sensors are identical to those shown in FIG. 8, except that MgO_{X} barrier layers 210 have various thicknesses as labeled at symbols in a unit of nm. After replacing the Co—Fe—B sense layer 264 with the Co-rich Co—Fe sense layer 364 in TMR read sensors with 0.695, 0.710, 0.725, 0.740 and 0.755 nm thick MgO_{X} barrier layers 210, R_{J}A_{J} decreases from 0.48, 0.54, 0.61, 0.69 and 0.80 Ω-μm² to 0.47, 0.53, 0.59, 0.67 and 0.80 Ω-μm², respectively (by 0.01, 0.01, 0.02, 0.02 and 0 Ω-μm², respectively), and H_{F} decreases from 169.1, 138.8, 118.1, 102.5 and 93.2 Oe to 133.7, 113.2, 96.4, 82.1 and 72.7 Oe, respectively (by 35.4, 25.6, 21.7, 20.4 and 20.5 Oe, respectively).

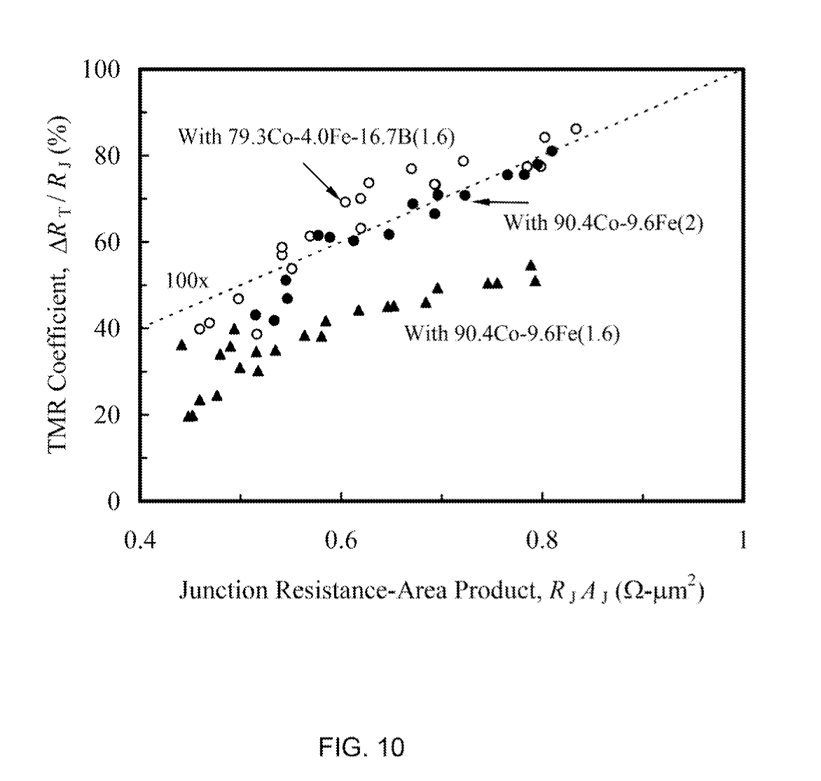

FIG. 10 shows R_{J}A_{J} versus ΔR_{T}/R_{J} for TMR read sensors with a 1.6 nm thick Co—Fe—B sense layer 264, and 1.6 and 2 nm thick Co-rich Co—Fe sense layers 364 after annealing for 5 hours at 280° C. In addition to the two types of the TMR read sensors identical to those shown in FIG. 9, the third type of the TMR sensor comprises a 1.6 nm thick Co-rich Co—Fe sense layer 364 and a 3.8 nm thick Ni—Fe sense layer 268. By simply replacing the 1.6 nm thick Co—Fe—B sense layer 264 with a 0.9 nm thick Co-rich Co—Fe sense layers 364, the read gap will decrease by 0.7 nm, but the scattering path of the sense layer structure 228 will also decrease by 0.7 nm. With the scattering path of as short as 1.1 nm, ΔR_{T}/R_{J} is expected to be very low. Even when the Co-rich Co—Fe sense layer 364 is as thick as the Co—Fe—B sense layer 264 and thus the scattering path becomes identical in the both TMR read sensors, ΔR_{T}/R_{J} is still low, as shown in FIG. 10. However, when its thickness increases to 2.0 nm, ΔR_{T}/R_{J} becomes comparable with that of the TMR read sensor 201 with the 1.6 nm thick Co—Fe—B sense layer 264. In other words, by increasing the scattering path, the Co-rich sense layer 364 can function as well as the Co—Fe—B sense layer 264, and thus the Co-rich sense layer 364 can replace the entire Co—Fe—B sense layer 264. Since the Co-rich sense layer 364 exhibits a magnetization damping constant much lower than the Co—Fe—B sense layer 264, it is expected to minimize magnetization damping and thus reduce magnetic noises in magnetic recording.

However, to maintain the sense-layer saturation moment unchanged, the replacement of the 1.6 nm thick Co—Fe—B sense layer 264 with the 2.0 nm thick Co-rich Co—Fe sense layer 364 requires the Ni—Fe sense layer 368 to be thinner than the Ni—Fe sense layer 268 by as large as 2.8 nm. The Ni—Fe sense layer 368 does not affect the tunneling, but plays a key role in attaining good soft ferromagnetic properties. For example, by decreasing the thickness of the Ni—Fe sense layer 368 from 5.6 to 2.8 and 0.8 nm for designs of the sense-layer saturation moment of 0.56 and 0.42 memu/cm², respectively (corresponding to that of 8 and 6 nm thick ferromagnetic 88Ni-12Fe films sandwiched between two Cu films, respectively), λ_{S} increases from −4.17×10⁻⁶ to −1.41×10⁻⁶ and 1.61×10⁻⁶, respectively. To maintain a more negative λ_{S}, Fe atoms which dominates λ_{S} may be eliminated by replacing the 2.8 and 0.8 nm thick Ni—Fe sense layers 368 with 3.2 and 1 nm thick Ni sense layers with M_{S} of 463 emu/cm³, respectively, and atomic mixing at an interface between the sense layer structure 328 and the cap layer structure 230 may be reduced by replacing the Ru first cap layer with a Pt cap layer.

FIGS. 8, 9 and 10 thus suggest a replacement of the Co—Fe—B sense layer 264 with the Co-rich Co—Fe sense layer 364 and a decrease in the thickness of the Ni—Fe sense layer 368. For a TMR read sensor with a designed R_{J}A_{J} of 0.6 Ω-μm², δ_{MgOx}^{N} will increase from 0.722 to 0.728 nm (by 0.006 nm), H_{F}^{N} will decrease from 121.8 to 93.2 Oe (by 28.6 Oe), and FoM^{N} will decrease by 104.8 to 101.6 (by 3.2).

Since the reference layer structure 324, the barrier layer 210 and the sense layer structure 328 are deposited independently in three different deposition modules in accordance with the invention, all the metal/metal interfaces in the reference layer structure 324 and the sense layer structure 328 are in-situ formed, but the metal/oxide and oxide/metal interfaces are still ex-situ formed. In a method of further decreasing R_{C2} and R_{C3} in accordance with the invention, the Co—Fe reference layer 358, the MgO_{X} barrier layer 210 and the Fe-rich Co—Fe sense layer 362 are also sequentially in-situ deposited on a wafer in a deposition module of a sputtering system. Without transfers through a transfer module to different deposition modules for depositions, low-R_{C2} metal/oxide and low-R_{C3} oxide/metal interfaces are immediately in-situ formed. The in-situ formed metal/metal, metal/oxide and oxide/metal interfaces may ensure the cleanness of the scattering path in the reference layer structure 324, the MgO_{X} barrier layer 210 and the sense layer structure 328, so that saturation moments can be precisely controlled and conduction electrons can be effectively scattered to attain a strong tunneling effect.

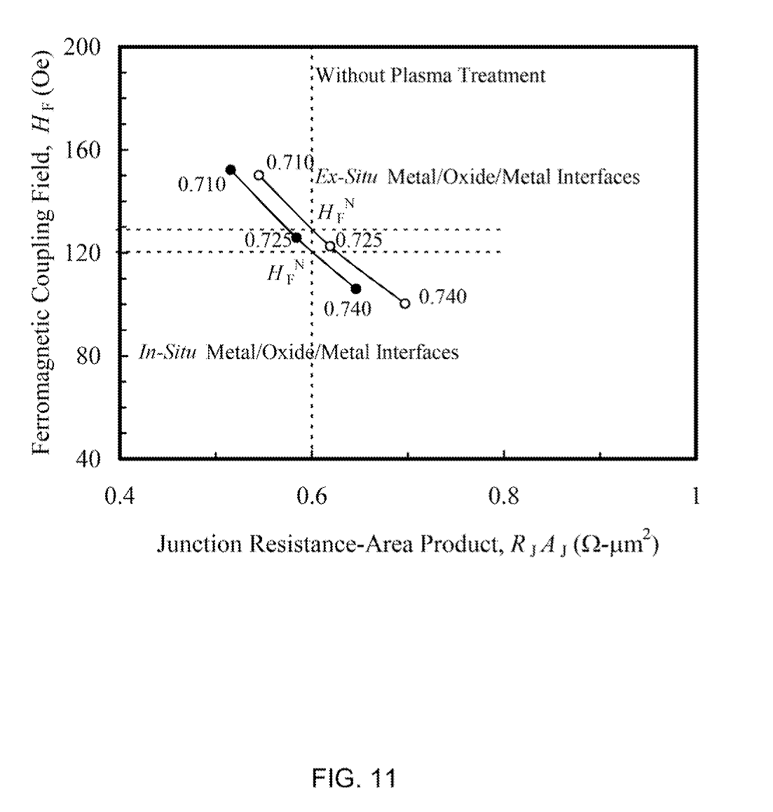

FIG. 11 shows R_{J}A_{J} versus H_{F} for TMR read sensors 301 with various δ_{MgOx} (labeled at symbols in a unit of nm) and with ex-situ and in-situ metal/oxide/metal interfaces after annealing for 5 hours at 280° C. The TMR read sensor 301 comprises Ta(2)/Ru(2)/Ir—Mn(6)/Co—Fe(1.8)/Co(0.4)/Ru(0.4)/Co(0.4)/Co—Hf(0.4)/Co—Fe—B(0.6)/Co—Fe(0.8)/MgO_{X}/Co—Fe(0.8)/Co—Fe—B(1.2)/Co—Hf(1.2)/Ni—Fe(4.8)/Ru(1)/Ta(1)/Ru(4) films, After the conversion from ex-situ to in-situ metal/oxide/metal interfaces for TMR read sensors with 0.710, 0.725 and 0.740 nm thick MgO_{X} barrier layers 210, R_{J}A_{J} decreases from 0.54, 0.62 and 0.70 Ω-μm² to 0.52, 0.58 and 0.65 Ω-μm², respectively, and H_{F} varies from 150.1, 122.5 and 100.2 Oe to 152.2, 125.9 and 106.0 Oe, respectively.

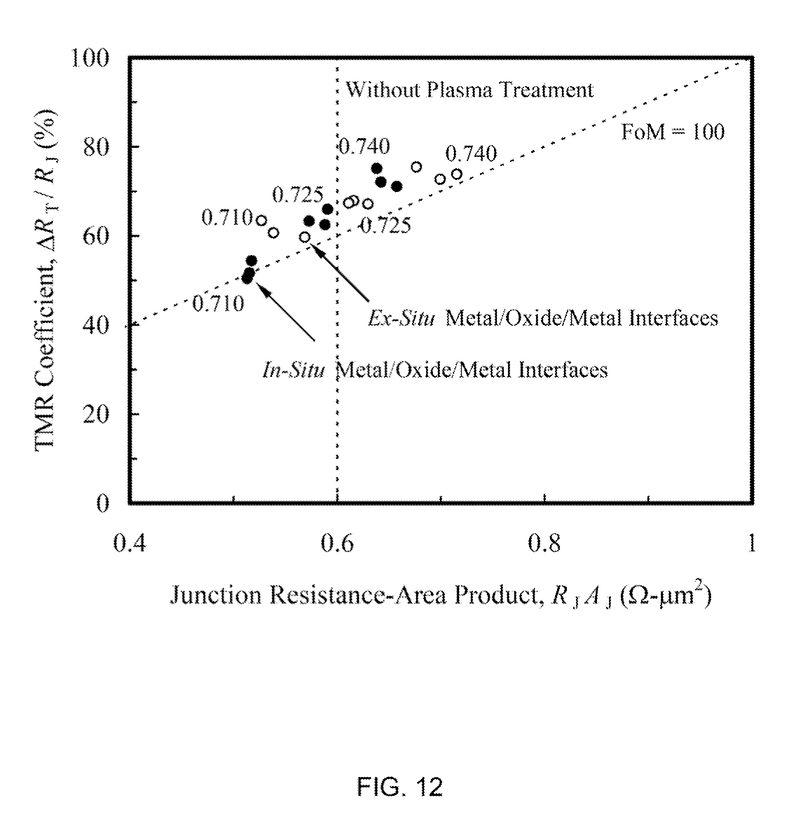

FIG. 12 shows R_{J}A_{J} versus ΔR_{T}/R_{J} for TMR read sensors 301 with various δ_{MgOx} and with ex-situ and in-situ metal/oxide/metal interfaces after annealing for 5 hours at 280° C. The TMR read sensors 301 are identical to those shown in FIG. 11. After the conversion from ex-situ to in-situ metal/oxide/metal interfaces for TMR read sensors with 0.710, 0.725 and 0.740 nm thick MgO_{X} barrier layers 210, ΔR_{T}/R_{J} decreases from 61.3, 67.5 and 74.0% to 52.2, 63.9 and 72.8%, respectively, and FoM varies from 112.5, 109.0 and 106.1 to 101.2, 109.5 and 112.6, respectively.

FIGS. 11 and 12 suggest the conversion from ex-situ to in-situ metal/oxide/metal interfaces. For a TMR read sensor with a designed R_{J}A_{J} of 0.6 Ω-μm², δ_{MgOx}^{N} will increase from 0.719 to 0.728 nm (by 0.009 nm), H_{F}^{N} will decrease from 129.0 to 120.4 Oe (by 8.6 Oe), and FoM^{N} will increase by 109.0 to 109.5 (by 0.5).

In summary, Table 3 lists various methods of attaining low-R_{C1} metal/metal, low-R_{C2} metal/oxide and low-R_{C3} oxide/metal interfaces in accordance with the invention, and their evaluation based on changes in δ_{MgOx}^{N}, H_{F}^{N} and FoM^{N} (δ_{MgOx}^{N}, ΔH_{F}^{N} and ΔFoM, respectively). To attain low-R_{C1} metal/metal, low-R_{C2} metal/oxide and low-R_{C3} oxide/metal interfaces in accordance with the invention, the plasma treatment is eliminated, thinner Co—Fe—B and thicker Co—Fe reference layers are used, the Co—Fe—B sense layer is replaced by the Co-rich Co—Fe sense layer, and in-situ metal/oxide/metal interfaces are formed. For a TMR read sensor with a designed R_{J}A_{J} of 0.6 Ω-μm², δ_{MgOx}^{N} will increase by 0.088 nm, H_{F}^{N} will decrease by 35.9 Oe, and FoM^{N} will decrease by 6.1.

TABLE 3

| | Δδ_{MgOx}^{N} | ΔH_{F}^{N} | |
|---|---|---|---|
| Method | (nm) | (Oe) | ΔFoM^{N} |
| No Plasma Treatment | 0.059 | 11.4 | −1.6 |
| Thinner Co—Fe—B/Thicker Co—Fe | 0.014 | −10.1 | −1.9 |
| Reference Layers | | | |
| Thicker Co—Fe/Thinner Co—Fe—B | 0 | −4.1 | −3.1 |
| Sense Layers | | | |
| Fe-rich Co—Fe/Co-rich Co—Fe | 0.006 | −28.6 | −3.2 |
| Sense Layers | | | |
| In-Situ Metal/Oxide/Metal TMR Interfaces | 0.009 | −8.6 | 0.5 |

While various embodiments have been described, it should be understood that they have been presented by way of example only, and not limitation. Other embodiments falling within the scope of the invention may also become apparent to those skilled in the art. Thus, the breadth and scope of the invention should not be limited by any of the above-described exemplary embodiments, but should be defined only in accordance with the following claims and their equivalents.

What is claimed is:

1. A read sensor, comprising:
a barrier layer sandwiched between a reference layer structure and a sense layer structure;
the reference layer structure comprising:
a first reference layer formed of a ferromagnetic Co film;
a second reference layer formed of a ferromagnetic Co—Hf film over the first reference layer;
a third reference layer formed of a ferromagnetic Co—Fe—B film over the second reference layer; and
a fourth reference layer formed of a ferromagnetic Co—Fe film over the third reference layer;
the sense layer structure comprising:
a first sense layer formed of a ferromagnetic Co—Fe film;
a second sense layer formed of a ferromagnetic Co—Fe—B film over the first sense layer;
a third sense layer formed of a ferromagnetic Co—Hf film over the second sense layer; and
a fourth sense layer formed of a ferromagnetic Ni—Fe film over the third sense layer.

2. The read sensor as in claim 1, wherein:
the second reference layer contains 66˜86 atomic percent Co and 14˜34 atomic percent Hf;
the third reference layer contains 55˜75 atomic percent Co, 10˜30 atomic percent Fe, and 5˜25 atomic percent B; and
the fourth reference layer contains 37˜57 atomic percent Co and 43˜63 atomic percent Fe.

3. The read sensor as in claim 1, wherein:
the first sense layer contains 37˜57 atomic percent Co and 43˜63 atomic percent Fe;
the second sense layer contains 69˜89 atomic percent Co, 0˜14 atomic percent Fe, and 7˜27 atomic percent B;
the third sense layer contains 66˜86 atomic percent Co and 14˜34 atomic percent Hf; and
the fourth sense layer contains 86˜100 atomic percent Ni and 0˜14 atomic percent Fe.

4. The read sensor as in claim 1, wherein:
the first reference layer has a thickness of 0.2˜0.6 nm;
the second reference layer has a thickness of 0.2˜0.6 nm;
the third reference layer has a thickness of 0.2˜1.0 nm; and
the fourth reference layer has a thickness of 0.4˜1.2 nm.

5. The read sensor as in claim 1, wherein:
the first sense layer has a thickness of 0.4˜1.2 nm;
the second sense layer has a thickness of 0.4˜2.0 nm;
the third sense layer has a thickness of about 0.6˜1.8 nm; and
the fourth sense layer has a thickness of about 2.4˜7.2 nm.

6. A read sensor, comprising:
a barrier layer sandwiched between a reference layer structure and a sense layer structure;
the reference layer structure comprising:
a first reference layer formed of a ferromagnetic Co film;
a second reference layer formed of a ferromagnetic Co—Hf film over the first reference layer;
a third reference layer formed of a ferromagnetic Co—Fe—B film over the second reference layer; and
a fourth reference layer formed of a ferromagnetic Co—Fe film over the third reference layer;
and
the sense layer structure comprising:
a first sense layer formed of a ferromagnetic Co—Fe film fifth layer;
a second sense layer formed of a ferromagnetic Co—Fe film over the first sense layer;
a third sense layer formed of a ferromagnetic Co—Hf film over the second sense layer; and
a fourth sense layer formed of a ferromagnetic Ni—Fe film over the third sense layer.

7. The read sensor as in claim 6 wherein the second sense layer has a lower Fe content than the first sense layer.

8. The read sensor as in claim 6, wherein:
the second reference layer contains 66˜86 atomic percent Co and 14˜34 atomic percent Hf;
the third reference layer contains 55˜75 atomic percent Co, 10˜30 atomic percent Fe, and 5˜25 atomic percent B; and
the fourth reference layer contains 37˜57 atomic percent Co and 43˜63 atomic percent Fe.

9. The read sensor as in claim 6, wherein:
the first sense layer contains 37˜57 atomic percent Co and 43˜63 atomic percent Fe;
the second sense layer contains 80˜100 atomic percent Co and 0˜20 atomic percent Fe;
the third sense layer contains 66˜86 atomic percent Co and 14˜34 (or about 24) atomic percent Hf; and
the fourth sense layer contains 86˜100 atomic percent Ni and 0˜14 atomic percent Fe.

10. The read sensor as in claim 1, wherein:
the first reference layer has a thickness of 0.2˜0.6 nm;
the second reference layer has a thickness of 0.2˜0.6 nm;
the third reference layer has a thickness of 0.2˜1.0 nm; and
the fourth reference layer has a thickness of 0.4˜1.2 nm.

11. The read sensor as in claim 1, wherein:
the first sense layer has a thickness of 0.4˜1.2 nm;
the second sense layer has a thickness of 1.0˜3.0 nm;
the third sense layer has a thickness of about 0.6˜1.8 nm; and
the fourth sense layer has a thickness of about 2.4˜7.2 nm.

12. A method of manufacturing a read sensor, comprising:
depositing a reference layer structure;
depositing a barrier layer over the reference layer structure; and
depositing a sense layer structure over the barrier layer;
the deposition of the reference layer structure further comprising:
depositing a first reference layer formed of a ferromagnetic Co film;
depositing a second reference layer formed of a ferromagnetic Co—Hf film over the first reference layer;
depositing a third reference layer formed of a ferromagnetic Co—Fe—B film over the second reference layer, and
depositing a fourth reference layer formed of a ferromagnetic Co—Fe film over the third reference layer;
the deposition of the sense layer structure further comprising;
depositing a first sense layer formed of a ferromagnetic Co—Fe film;
depositing a second sense layer formed of a ferromagnetic Co—Fe—B film over the first sense layer;
depositing a third sense layer formed of a ferromagnetic Co—Hf film over the second sense layer; and
depositing a fourth sense layer formed of a ferromagnetic Ni—Fe film over the third sense layer.

13. The method as in claim 12 wherein all the reference layers are in-situ deposited in a high-vacuum deposition module of a sputtering system, without wafer transfers and plasma etching in other modules.

14. The method as in claim 12 wherein all the sense layers are in-situ deposited in a high-vacuum deposition module of a sputtering system, without wafer transfers and plasma etching in other modules.

15. The method as in claim 12 wherein the fourth reference layer, the barrier layer and the first sense layer are in-situ deposited in a high-vacuum deposition module of a sputtering system, without wafer transfers and plasma etching in other deposition modules.

16. A method of manufacturing a read sensor, comprising:
depositing a reference layer structure;
depositing a barrier layer over the reference layer structure; and
depositing a sense layer structure over the barrier layer;
the deposition of the reference layer structure further comprising:
depositing a first reference layer formed of a ferromagnetic Co film;
depositing a second reference layer formed of a ferromagnetic Co—Hf film over the first reference layer;
depositing a third reference layer formed of a ferromagnetic Co—Fe—B film over the second reference layer; and
depositing a fourth reference layer formed of a ferromagnetic Co—Fe film over the third reference layer;
the deposition of the sense layer structure further comprising;
depositing a first sense layer formed of a ferromagnetic Co—Fe film;
depositing a second sense layer formed of a ferromagnetic Co—Fe film over the first sense layer;
depositing a third sense layer formed of a ferromagnetic Co—Hf film over the second sense layer; and
depositing a fourth sense layer formed of a ferromagnetic Ni—Fe film over the third sense layer.

17. The method as in claim 16 wherein all the reference layers are in-situ deposited in a high-vacuum deposition module of a sputtering system, without wafer transfers and plasma etching in other modules.

18. The method as in claim 16 wherein all the sense layers are in-situ deposited in a high-vacuum deposition module of a sputtering system, without wafer transfers and plasma etching in other modules.

19. The method as in claim 16 wherein the fourth reference layer, the barrier layer and the first sense layer are in-situ deposited in a high-vacuum deposition module of a sputtering system, without wafer transfers and plasma etching in other modules.
